(19) United States
(12) Patent Application Publication
(10) Pub. No.: US 2012/0157010 A1
(43) Pub. Date: Jun. 21, 2012

(54) Electrical Power Amplifier Circuit, and Transmission Device and Communication Device Using the Same

(75) Inventors: Yasuhiko Fukuoka, Soraku-gun (JP); Akira Nagayawa, Kunitachi-shi (JP)

(73) Assignee: KYOCERA CORPORATION, Kyoto-shi, Kyoto (JP)

(21) Appl. No.: 13/392,080

(22) PCT Filed: Jul. 29, 2010
(86) PCT No.: PCT/JP2010/062820

§ 371 Date: Feb. 23, 2012

(30) Foreign Application Priority Data
Aug. 27, 2009 (JP) 2009-196316

(51) Int. Cl. H04B 1/04; H04B 1/38; H03G 3/20

(52) U.S. Cl. 455/73; 330/278; 455/127.1

(57) ABSTRACT

The power amplifier circuit includes: a constant envelope signal generation circuit (100) which outputs two constant envelope signals; transistors (11, 12) including sources and gates which are supplied with the output signals from the constant envelope signal generation circuit; a variable gain amplifier (21) which amplifies an output signal from the transistor (11); a gain control circuit (40) which controls so that a gain of the variable gain amplifier (21) is increased when an amplitude of an input signal is smaller than a predetermined value; a transistor (13) including a gate supplied with an output signal from the variable gain amplifier (21) and a source which is grounded; a low-pass filter (32) connected between a drain of the transistor (13) and a power supply potential; and an output matching circuit (37) connected between the drain of the transistor (13) and an output terminal (38).

### TECHNICAL FIELD

The present invention relates to a power amplifier circuit used for amplifying a transmission signal or other purposes in a radio communication apparatus or the like. In particular, the present invention relates to a power amplifier circuit that can amplify a signal having an envelope fluctuation at highpower addition efficiency, and to a transmission device and a communication device using the power amplifier circuit.

### BACKGROUND ART

In radio communication for a wireless network or the like, digital modulated signals are used for communication in many cases. Most of the signals used for such communication contain information in a direction of the signal amplitude, and hence the signal has an envelope fluctuation. Therefore, the radio communication apparatus used for such communication needs to amplify the signal having an envelope fluctuation. On the other hand, the radio communication apparatus is required to have small power consumption for ensuring communication time, and an amplifier for amplifying the communication signal is also required to have low power consumption and high power addition efficiency. However, there is a problem that when the above-mentioned signal having an envelope fluctuation is amplified using a nonlinear amplifier having high power addition efficiency, a distortion may occur so that the signal is deteriorated. Therefore, there are proposed some methods for amplifying the signal having an envelope fluctuation at high power addition efficiency.

One of the methods is an amplification method called a linear amplification with nonlinear component (LINC) method. In this method, the signal having an envelope fluctuation is converted into two constant envelope signals, and afterward each of the two constant envelope signals is amplified using a nonlinear amplifier. Then, a vector addition of the amplified two constant envelope signals is performed so as to generate an amplified signal having an envelope fluctuation. Thus, a signal having an envelope fluctuation can be amplified at high power addition efficiency (see, for example, Patent Document 1).

### PATENT DOCUMENT

Patent Document 1: JP 1-284106 A

### DISCLOSURE OF THE INVENTION

### Problems to be Solved by the Invention

However, a power amplifier circuit using the above-mentioned conventional LINC method has a problem that if an amplitude of an input signal becomes small, power addition efficiency of the power amplifier circuit is decreased.

The present invention has been made in view of the above-mentioned problem of the conventional technology, and it is an object thereof to provide a power amplifier circuit in which a decrease of power addition efficiency due to a decrease in amplitude of an input signal is reduced, and a transmission device and a communication device using the power amplifier circuit. Means for Solving the Problems

A first power amplifier circuit according to the present invention includes: a constant envelope signal generation circuit that converts an input signal having an envelope fluctuation into a first constant envelope signal and a second constant envelope signal which have a phase difference that increases and decreases oppositely to an increase and a decrease of an amplitude of the input signal, and outputs the first constant envelope signal and the second constant envelope signal; a first transistor including a source terminal supplied with the first constant envelope signal, and a gate terminal supplied with a signal having the same phase as a phase of the second constant envelope signal; a second transistor including a source terminal supplied with the second constant envelope signal, and a gate terminal supplied with a signal having the same phase as a phase of the first constant envelope signal; a first variable gain amplifier that amplifies a signal output from a drain terminal of the first transistor and outputs the amplified signal; a third transistor including a source terminal connected to a reference potential, a drain terminal connected to a power supply potential via a first low-pass filter, and a gate terminal supplied with an output signal of the first variable gain amplifier, in which an output signal from the drain terminal is delivered via an output matching circuit; and a gain control circuit that is supplied with a part of the input signal and outputs a gain control signal for controlling the first variable gain amplifier so that a gain of the first variable gain amplifier is increased when the amplitude of the input signal is smaller than a predetermined value.

A second power amplifier circuit according to the present invention further includes, in the first power amplifier circuit: a second variable gain amplifier that amplifies a signal output from a drain terminal of the second transistor and outputs the amplified signal; and a fourth transistor including a source terminal connected to the reference potential, a drain terminal connected to the power supply potential via a second low-pass filter, and a gate terminal supplied with an output signal of the second variable gain amplifier, in which an output signal from the drain terminal is delivered via the output matching circuit, in which the gain control circuit outputs a gain control signal for controlling the first variable gain amplifier and the second variable gain amplifier so that gains of the first variable gain amplifier and the second variable gain amplifier are increased when the amplitude of the input signal is smaller than the predetermined value.

A transmission device of the present invention includes a transmission circuit and an antenna that are connected via the power amplifier circuit having the above-mentioned configuration.

A communication device of the present invention includes a transmission circuit and an antenna that are connected via the power amplifier circuit having the above-mentioned configuration, and a reception circuit connected to the antenna.

### Effect of the Invention

According to the power amplifier circuit of the present invention, the power amplifier circuit having small power consumption and high power addition efficiency can be obtained.

### BRIEF DESCRIPTION OF THE DRAWINGS

FIG. 1 is a block diagram schematically illustrating a power amplifier circuit of a first example of an embodiment of the present invention.

FIG. 2 is a circuit diagram schematically illustrating an example of a constant envelope signal generation circuit of FIG. 1.

FIG. 3 is a block diagram schematically illustrating a power amplifier circuit of a second example of the embodiment of the present invention.

FIG. 4 is a block diagram illustrating a transmission device of a third example of the embodiment of the present invention.

FIG. 5 is a block diagram illustrating a communication device of a fourth example of the embodiment of the present invention.

FIG. 6 is a graph illustrating a simulation result of an electrical characteristic of a power amplifier circuit of a comparative example, and FIG. 6(b) is a graph illustrating a simulation result of an electrical characteristic of the power amplifier circuit of the second example of the embodiment of the present invention.

### BEST MODE FOR CARRYING OUT THE INVENTION

Hereinafter, a power amplifier circuit of the present invention is described in detail with reference to the attached drawings.

### First Example of Embodiment

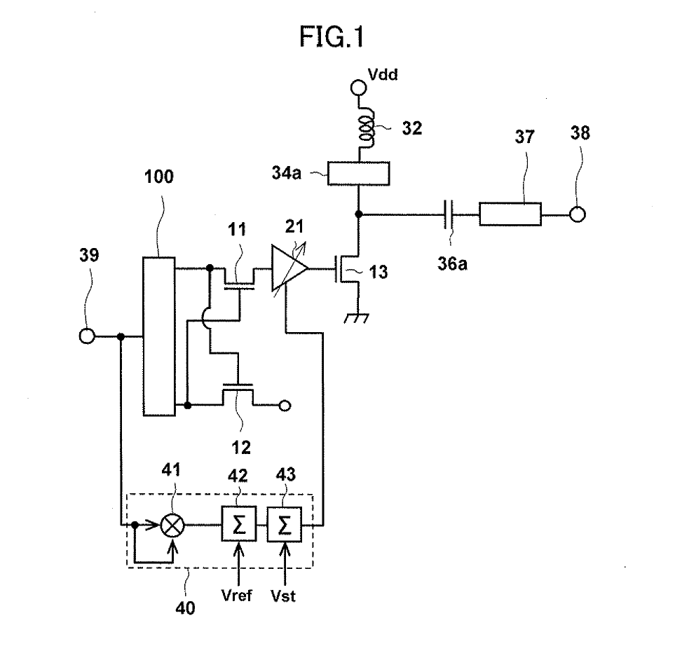

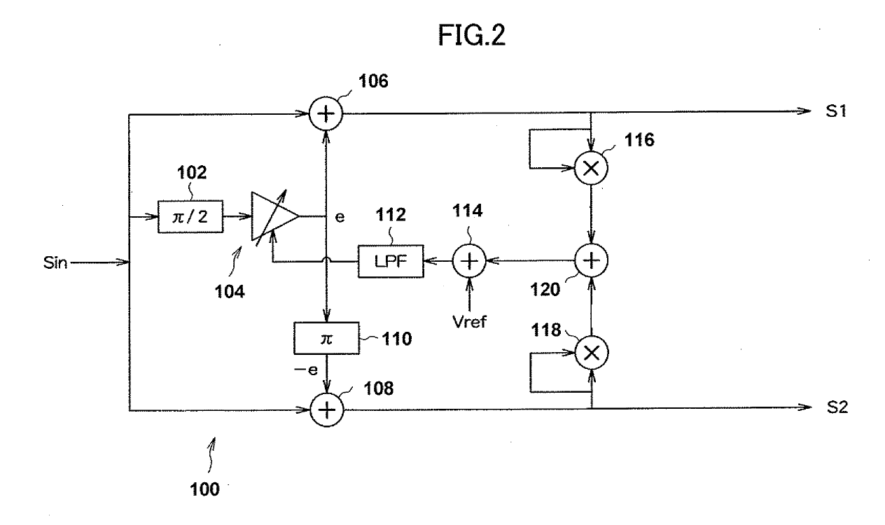

FIG. 1 is a circuit diagram illustrating a power amplifier circuit of a first example of an embodiment of the present invention. FIG. 2 is a circuit diagram illustrating an example of a constant envelope signal generation circuit of FIG. 1.

The power amplifier circuit of this example includes, as illustrated in FIG. 1, an input terminal 39, a constant envelope signal generation circuit 100, a first transistor 11, a second transistor 12, a first variable gain amplifier 21, a gain control circuit 40, a third transistor 13, a first low-pass filter 32, a harmonic matching circuit 34a, a capacitor 36a, an output matching circuit 37, and an output terminal 38.

The constant envelope signal generation circuit 100 converts an input signal having an envelope fluctuation supplied from the input terminal 39 into a first constant envelope signal and a second constant envelope signal having a phase difference that increases or decreases oppositely to an increase or decrease in amplitude of the input signal, and outputs the result. The first transistor 11 is supplied with the first constant envelope signal at a source terminal and the second constant envelope signal at a gate terminal. The second transistor 12 is supplied with the second constant envelope signal at a source terminal and the first constant envelope signal at a gate terminal. The first variable gain amplifier 21 amplifies a signal output from a drain terminal of the first transistor 11, and outputs the amplified signal.

In addition, the third transistor 13 has a source terminal connected to a reference potential (ground potential), a drain terminal connected to a power supplypotential via the first low-pass filter 32, and a gate terminal that is supplied with the output signal of the first variable gain amplifier 21, and hence an output signal from the drain terminal is delivered via the output matching circuit 37. The first low-pass filter 32 is disposed for preventing a high frequency signal from flowing out, and is constituted of an inductor. In addition, the first low-pass filter 32 has one end connected to the drain terminal of the third transistor 13 via the harmonic matching circuit 34a and the other end connected to a power supply potential Vdd. The output matching circuit 37 has one end connected to the drain terminal of the third transistor 13 and to the harmonic matching circuit 34a via the capacitor 36a, and the other end connected to the output terminal 38. Note that, each of the first transistor 11 to the third transistor 13 is an n-channel FET, and a pinch-off voltage thereof (threshold voltage for enabling a drain current to flow) is denoted by Vp.

The output matching circuit 37 provides matching of impedance of the output terminal 38 viewed from the drain terminal of the third transistor 13 by a fundamental wave. The harmonic matching circuit 34a sets the impedance to be a short circuit for evenharmonics of the fundamental wave and to be open for odd harmonics of the fundamental wave. Therefore, the third transistor 13 performs a class F operation. Note that, if the third transistor 13 does not perform the class F operation, the harmonic matching circuit 34a is not necessary.

The capacitor 36a is a DC-cut capacitor. Note that, a bias Vb (≦Vp) is applied to the gate terminals of the first transistor 11 to the third transistor 13 by a bias circuit (not shown). Thus, the first transistor 11 to the third transistor 13 are turned on when each gate terminal is supplied with a voltage higher than an ON voltage Von=Vp-Vb.

Note that, a drain terminal of the second transistor 12 is terminated by a predetermined impedance (not shown), but the drain terminal of the second transistor 12 may be connected to an input terminal of the first variable gain amplifier 21 in some cases.

In addition, the output signal of the drain terminal of the second transistor 12 may be used in other circuits. In addition, the first transistor 11 and the second transistor and 12 constitute a transfer gate circuit. The first transistor 11 is turned on only when a voltage of the second constant envelope signal is larger than Von so as to permit the first constant envelope signal to pass through. Thus, the third transistor 13 is turned on only in a period while both the first constant envelope signal and the second constant envelope signal are larger than Von. Therefore, compared with a case where the first constant envelope signal is applied as it is to the gate terminal of the third transistor 13, the turn-on period of the third transistor 13 is shortened. Therefore, power consumption is reduced, and power supply efficiency (a ratio of output power to power supplied from the constant voltage supply Vdd) is improved. As a result, a power amplifier circuit having high power addition efficiency can be obtained.

Note that, the period in which both the first constant envelope signal and the second constant envelope signal are larger than Von is generated every fundamental period, and hence the period in which the third transistor 13 is turned on is generated every fundamental period. Therefore, a drain voltage of the third transistor 13 also contains a fundamental wave component. Therefore, the output matching circuit 37 extracts the fundamental wave component from the drain voltage of the third transistor 13 and the extracted component is output from the output terminal 38. The amplitude of the output signal from the output terminal 38 increases or decreases along with an increase or decrease of the period in which both the first constant envelope signal and the second constant envelope signal are larger than Von, and hence the amplitude increases or decreases oppositely to an increase or decrease of the phase difference between the first constant envelope signal and the second constant envelope signal. In other words, the output signal from the output terminal 38 has an amplitude that increases or decreases in accordance with an increase or decrease in amplitude of the input signal, and is an amplified signal of the input signal.

The gain control circuit 40 includes a mixer 41, a first adder circuit 42, and a second adder circuit 43. The mixer 41 is supplied with a part of the input signal and outputs an amplitude detection signal having a DC voltage corresponding to the amplitude of the input signal. The first adder circuit 42 is supplied with a reference signal Vref having a predetermined DC voltage and the amplitude detection signal from the mixer 41, and outputs a gain control base signal having a voltage obtained by subtracting a voltage of the amplitude detection signal from a voltage of the reference signal Vref. If the voltage of the amplitude detection signal is larger than the voltage of the reference signal Vref, a voltage of the gain control base signal becomes zero. The second adder circuit is supplied with a reference signal Vst having a predetermined DC voltage and the gain control base signal from the first adder circuit, and outputs a gain control signal having a DC voltage obtained by adding a voltage of the reference signal Vst and the voltage of the gain control base signal. Therefore, the DC voltage of the gain control signal increases if the amplitude of the input signal is smaller than a predetermined value, and an increase amount thereof increases or decreases oppositely to an increase or decrease of the amplitude of the input signal. Through use of this gain control signal for controlling a gain of the first variable gain amplifier 21, it is possible to control the gain of the first variable gain amplifier 21 so that the gain of the first variable gain amplifier 21 increases when the amplitude of the input signal is smaller than the predetermined value, and that the increase amount thereof increases or decreases oppositely to an increase or decrease of the amplitude of the input signal. Note that, the amplitude of the input signal at which the gain of the first variable gain amplifier 21 starts to increase can be determined by a DC voltage of the reference signal Vref supplied to the first adder circuit 42.

When the amplitude of the input signal decreases, a phase difference between the first constant envelope signal and the second constant envelope signal increases. Because the first constant envelope signal and the second constant envelope signal are not complete rectangular signals, as the phase difference between the first constant envelope signal and the second constant envelope signal becomes larger, an amplitude of the signal passing through the transfer gate circuit constituted of the first transistor 11 and the second transistor 12 becomes smaller. Therefore, if the first variable gain amplifier 21 is not provided, there occurs a problem that the third transistor 13 cannot be turned on.

According to a detector circuit of this example having the above-mentioned structure, it is possible to increase a voltage of the signal supplied to the gate terminal of the third transistor 13 by increasing the gain of the first variable gain amplifier 21 when the amplitude of the input signal is smaller than the predetermined value. Thus, it is possible to reduce occurrence of the problem that the third transistor 13 cannot be turned on when the amplitude of the input signal becomes small. Therefore, the problem that the power addition efficiency is decreased when the amplitude of the input signal becomes small can be addressed.

As described above, according to the power amplifier circuit of this example, it is possible to obtain the power amplifier circuit having high power addition efficiency, in which a decrease of the power addition efficiency due to a decrease of the amplitude of the input signal can be reduced.

FIG. 2 is a circuit diagram illustrating an example of the constant envelope signal generation circuit 100 of FIG. 1. As illustrated in FIG. 2, the constant envelope signal generation circuit 100 includes a phase shifter 102, a variable gain amplifier 104, an adder circuit 106, a phase shifter 110, an adder circuit 108, a mixer 116, a mixer 118, an adder circuit 120, an adder circuit 114, and a low-pass filter 112. The phase shifter 102 advances the phase of an input signal Sin by n/2 and outputs the result. The variable gain amplifier 104 amplifies the output signal of the phase shifter 102 so as to generate a first signal e. The adder circuit 106 performs a vector addition of the first signal e and the input signal Sin so as to generate a first constant envelope signal Si. In addition, the phase shifter 110 delays the first signal e by n so as to generate a second signal −e. The adder circuit 108 performs a vector addition of the second signal −e and the input signal Sin so as to generate a second constant envelope signal S2. The mixer 116 outputs a signal having a voltage corresponding to an amplitude of the first constant envelope signal S1 (specifically, a square of the amplitude). The mixer 118 outputs a signal having a voltage corresponding to an amplitude of the second constant envelope signal S2 (specifically, a square of the amplitude). The adder circuit 120 adds output signals of the mixers 116 and 118, and outputs the result. The adder circuit 114 generates a signal having a voltage corresponding to the difference between a voltage of the output signal of the adder circuit 120 and the predetermined voltage Vref. The output signal of the adder circuit 114 is supplied to the variable gain amplifier 104 as the gain control signal via the low-pass filter 112 and a buffer amplifier (not shown). In this way, feedback control of a gain of the variable gain amplifier 104 is performed so that a sum of squares of amplitudes of the first constant envelope signal S1 and the second constant envelope signal S2 becomes a constant value. Thus, the first constant envelope signal Si and the second constant envelope signal S2 become constant envelope signals having a phase difference that increases or decreases oppositely to an increase or decrease of the input signal.

### Second Example of Embodiment

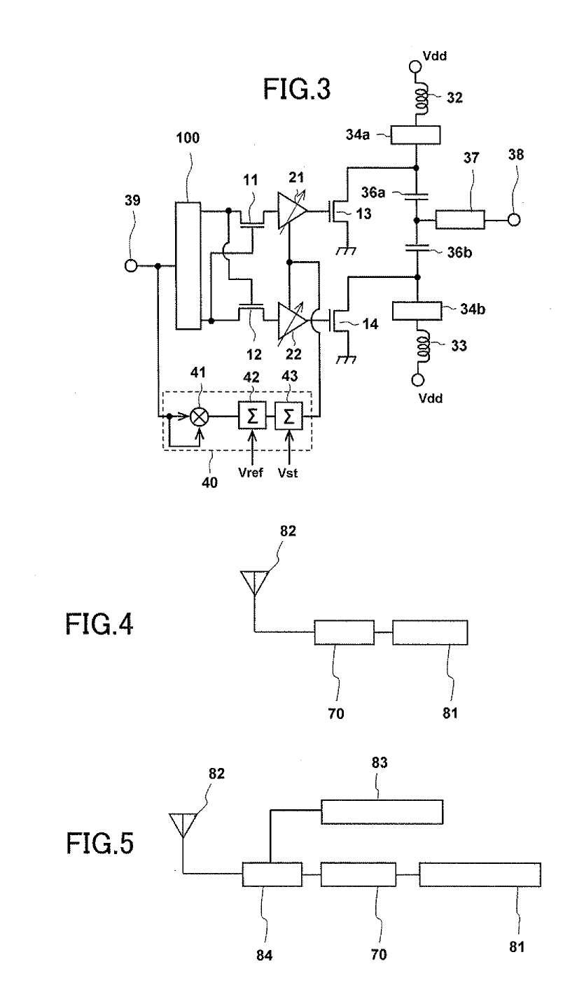

FIG. 3 is a circuit diagram illustrating a power amplifier circuit of a second example of the embodiment of the present invention. Note that, this example describes points different from the power amplifier circuit of the first example of the embodiment described above, and the same element is denoted by the same reference symbol so as to omit overlapping description.

As illustrated in FIG. 3, the power amplifier circuit of this example further includes a second variable gain amplifier 22, a fourth transistor 14, a second low-pass filter 33, a harmonic matching circuit 34b, and a capacitor 36b.

The second variable gain amplifier 22 amplifies the signal output from the drain terminal of the second transistor 12, and outputs the result. The fourth transistor 14 has a source terminal connected to the reference potential (ground potential), a drain terminal connected to the power supply potential via the second low-pass filter 33, and a gate terminal supplied with the output signal of the second variable gain amplifier 22. The output signal from the drain terminal is delivered via the output matching circuit 37. The second low-pass filter 33 is disposed for preventing a high frequency signal from flowing out, and is constituted of an inductor. In addition, the second low-pass filter 33 has one end connected to the drain terminal of the fourth transistor 14 via the harmonic matching circuit 34b and the other end connected to the power supply potential Vdd. The harmonic matching circuit 34b sets the impedance to be a short circuit for even harmonics of the fundamental wave and to be open for odd harmonics of the fundamental wave. Therefore, the fourth transistor 14 performs a class F operation. Note that, if the fourth transistor 14 does not perform the class F operation, the harmonic matching circuit 34b is not necessary. The capacitor 36b is a DC-cut capacitor.

The output matching circuit 37 in this example provides matching of impedance of the output terminal 38 viewed from the drain terminal of the third transistor 13 with impedance of the output terminal 38 viewed from the drain terminal of the fourth transistor 14 for the fundamental wave. In addition, the fourth transistor 14 is an n-channel FET, and a pinch-off voltage thereof (threshold voltage for enabling a drain current to flow) is denoted by Vp. Further, a bias Vb (≦Vp) is applied to the gate terminal of the fourth transistor 14 by a bias circuit (not shown), and the fourth transistor 14 is turned on when the gate terminal is supplied with a voltage higher than an ON voltage Von (=Vp-Vb).

The first transistor 11 and the second transistor 12 constitute a transfer gate circuit, and the second transistor 12 is turned on only when a voltage of the first constant envelope signal is larger than Von so as to permit the second constant envelope signal to pass through. Thus, the fourth transistor 14 is turned on only in a period while both the first constant envelope signal and the second constant envelope signal are larger than Von. Therefore, compared with a case where the second constant envelope signal is applied as it is to the gate terminal of the fourth transistor 14, the turn-on period of the fourth transistor 14 is shortened. Therefore, power consumption is reduced, and power supply efficiency (a ratio of output power to power supplied from the constant voltage supply Vdd) is improved. As a result, a power amplifier circuit having high power addition efficiency can be obtained.

Note that, the period in which both the first constant envelope signal and the second constant envelope signal are larger than Von is generated every fundamental period, and hence the period in which the third transistor 13 and the fourth transistor 14 are turned on is generated every fundamental period. Therefore, drainvoltages of the third transistor 13 and the fourth transistor 14 also contain a fundamental wave component. Therefore, the output matching circuit 37 extracts the fundamental wave component from the drain voltages of the third transistor 13 and the fourth transistor 14, and a fundamental wave component of a combined signal of the first constant envelope signal and the second constant envelope signal is output from the output terminal 38. The amplitude of the output signal from the output terminal 38 increases or decreases along with an increase or decrease of the period in which both the first constant envelope signal and the second constant envelope signal are larger than Von, and hence the amplitude increases or decreases oppositely to an increase or decrease of the phase difference between the first constant envelope signal and the second constant envelope signal. In other words, the output signal from the output terminal 38 has an amplitude that increases or decreases in accordance with an increase or decrease in amplitude of the input signal, and is an amplified signal of the input signal.

The power amplifier circuit of this example uses the above-mentioned gain control signal for controlling the gains of the first variable gain amplifier 21 and the second variable gain amplifier 22. Thus, if the amplitude of the input signal is smaller than a predetermined value, the gains of the first variable gain amplifier 21 and the second variable gain amplifier 22 are increased so as to increase voltages of signals supplied to the gate terminals of the third transistor 13 and the fourth transistor 14. In this way, it is possible to reduce occurrence of the problem that the third transistor 13 and the fourth transistor 14 cannot be turned on when the amplitude of the input signal becomes small. Therefore, the problem that the power addition efficiency is decreased when the amplitude of the input signal becomes small can be addressed. Thus, according to the power amplifier circuit of this example, it is possible to obtain the power amplifier circuit having high power addition efficiency, in which a decrease of the power addition efficiency due to a decrease of the amplitude of the input signal can be reduced.

### Third Example of Embodiment

FIG. 4 is a block diagram illustrating a transmission device of a third example of the embodiment of the present invention. As illustrated in FIG. 4, the transmission device of this example includes a transmission circuit 81, which is connected to an antenna 82 via a power amplifier circuit 70 illustrated in FIG. 1. Note that, the input terminal 39 of the amplifier circuit 70 illustrated in FIG. 1 is connected to the transmission circuit 81 and the output terminal 38 of the amplifier circuit 70 is connected to the antenna 82. According to the transmission device of this example having the above-mentioned structure, a transmission signal having an envelope fluctuation output from the transmission circuit 81 can be amplified using the power amplifier circuit 70 having small power consumption and high power addition efficiency. Therefore, it is possible to obtain the transmission device having small power consumption and long transmission time.

### Fourth Example of Embodiment

FIG. 5 is a block diagram illustrating a communication device of a fourth example of the embodiment of the present invention. As illustrated in FIG. 5, the communication device of this example includes the transmission circuit 81, which is connected to the antenna 82 via the power amplifier circuit 70 illustrated in FIG. 1, and a reception circuit 83, which is connected to the antenna 82. Further, a common antenna circuit 84 is inserted between the antenna 82 and the transmission circuit 81 and between the antenna 82 and the reception circuit 83. Note that, the input terminal 39 of the amplifier circuit 70 illustrated in FIG. 1 is connected to the transmissioncircuit 81 and the output terminal 38 of the amplifier circuit 70 is connected to the antenna 82. According to the communication device of this example having the above-mentioned structure, a transmission signal having an envelope fluctuation output from the transmission circuit 81 can be amplified using the power amplifier circuit 70 having small power consumption and high power addition efficiency. Therefore, it is possible to obtain the transmission device having small power consumption and long transmission time.

### EXAMPLE

Next, a specific example of the power amplifier circuit of the present invention is described. An electrical characteristic of the power amplifier circuit of the second example of the embodiment of the present invention illustrated in FIG. 3 was calculated by a circuit simulation. Each of the transistors was an n-channel MOSFET, the power supply voltage was 1.5 V, and the input signal frequency was 850 MHz.

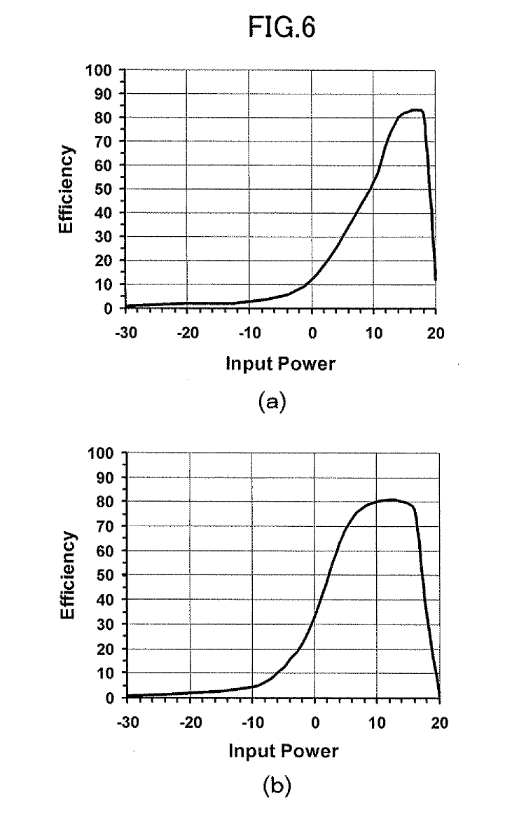

A result of the simulation is illustrated in FIG. 6(b). In addition, FIG. 6(a) illustrates a simulation result of a power amplifier circuit of a comparative example, in which the gain control circuit 40, the first variable gain amplifier 21, and the second variable gain amplifier 22 are removed from the power amplifier circuit illustrated in FIG. 3. In graphs of FIGS. 6(a) and 6(b), the horizontal axis represents electrical power of the input signal, and the vertical axis represents power addition efficiency of the power amplifier circuit.

According to the graph illustrated in FIG. 6(a), it is understood that high power addition efficiency over 80% is obtained as a peak, but the power addition efficiency is rapidly and sharply dropped along with a decrease of the electrical power of the input signal. In contrast, according to the graph illustrated in FIG. 6(b), it is understood that the peak value of the power addition efficiency is almost the same, but the drop of the power addition efficiency due to a decrease of the electrical power of the input signal does not occur soon, and the range of the electrical power of the input signal in which high power addition efficiency is maintained is expanded. Thus, effectiveness of the present invention was confirmed.

### REFERENCE SIGNS LIST

11: first transistor

12: second transistor

13: third transistor

14: fourth transistor

21: first variable gain amplifier

22: second variable gain amplifier

32: first low-pass filter

33: second low-pass filter

37: output matching circuit

38: output terminal

40: gain control circuit

70: power amplifier circuit

81: transmission circuit

82: antenna

83: reception circuit

100: constant envelope signal generation circuit

1. A power amplifier circuit, comprising:
a constant envelope signal generation circuit that converts an input signal having an envelope fluctuation into a first signal and a second signal, which are two constant envelope signals which have a phase difference that increases and decreases oppositely to an increase and a decrease of an amplitude of the input signal, and outputs the first signal and the second signal;
a first transistor including a source terminal supplied with the first signal, a gate terminal supplied with a signal having the same phase as a phase of the second signal, and a drain terminal which outputs a third signal;
a second transistor including a source terminal supplied with the second signal, a gate terminal supplied with a signal having the same phase as a phase of the first signal, and a drain terminal which outputs a fourth signal;
a first variable gain amplifier that amplifies the third signal and outputs a fifth signal;
a third transistor including a source terminal connected to a reference potential, a drain terminal connected to a power supply potential via a first low-pass filter, and a gate terminal supplied with the fifth signal, in which an output signal from the drain terminal is delivered via an output matching circuit; and
a gain control circuit that is supplied with a part of the input signal and outputs a signal for controlling the first variable gain amplifier so that a gain of the first variable gain amplifier is increased when the amplitude of the input signal is smaller than a predetermined value.

2. The power amplifier circuit according to claim 1, further comprising:
a second variable gain amplifier that amplifies the fourth signal and outputs a sixth signal; and
a fourth transistor including a source terminal connected to the reference potential, a drain terminal connected to the power supply potential via a second low-pass filter, and a gate terminal supplied with the sixth signal, in which an output signal from the drain terminal is delivered via the output matching circuit,
wherein the gain control circuit outputs a signal for controlling the first variable gain amplifier and the second variable gain amplifier so that gains of the first variable gain amplifier and the second variable gain amplifier are increased when the amplitude of the input signal is smaller than the predetermined value.

3. A transmission device, comprising:
a transmission circuit;
the power amplifier circuit according to claim 1; and
an antenna connected to the transmission circuit via the power amplifier circuit.

4. A communication device, comprising:
a transmission circuit and,
the power amplifier circuit according to claim 1;
an antenna connected to the transmission circuit via the power amplifier circuit; and
a reception circuit connected to the antenna.
